(19) United States
(12) Patent Application Publication
(10) Pub. No.: US 2026/0101592 A1
(43) Pub. Date: Apr. 9, 2026

(54) SEMICONDUCTOR DEVICE

(71) Applicant: United Microelectroics Corp., Hsinchu (TW)

(72) Inventors: Ting-Yao WANG, Hsinchu County (TW); Tien-Hao Tang, Hsinchu City (TW); Jin-San Lee, Hsinchu City (TW); Ching-Wei Li, Hsinchu City (TW)

(21) Appl. No.: 18/934,274

(22) Filed: Nov. 1, 2024

(30) Foreign Application Priority Data
Oct. 4, 2024 (TW) 113137888

(51) Int. Cl. H01L 27/02

(52) U.S. Cl. CPC H10D 89/814

(57) ABSTRACT

Semiconductor devices are provided. The semiconductor device includes a substrate, a source region in the substrate, a drain region in the substrate and having a drain sidewall facing toward the source region, a gate structure on the substrate and between the drain region and the source region, and a first well in the substrate and underneath the drain region. The gate structure has a first gate sidewall facing toward the drain region. The first well has a well sidewall facing toward the source region. A first distance between the first gate sidewall and the drain sidewall is less than or equal to a second distance between the first gate sidewall and the well sidewall.

This application claims the benefit of Taiwan application Serial No. 113137888, filed Oct. 4, 2024, the subject matter of which is incorporated herein by reference.

### BACKGROUND

### Technical Field

The disclosure relates to a semiconductor device, and more particularly relates to a semiconductor device including an electrostatic discharge protection structure.

### Description of the Related Art

Electrostatic discharge (ESD) is the transfer of electrostatic charge between different objects. The electrostatic discharge usually result in a flow of electric charge in a short period of time, and it may cause damage to semiconductor components when the electric charge flows into the semiconductor components. The electrostatic discharge protection structure can prevent the flow of electric charge which results from electrostatic discharge from passing through the semiconductor components by providing an electrostatic discharge path, thereby reducing or avoiding the harm caused by electrostatic charge. The electrostatic discharge protection structure usually needs to have a low breakdown voltage (VBD) and a low trigger voltage (Vₜ₁) to ensure its efficiency and reliability. During the electrostatic discharge process, if the breakdown voltage and the trigger voltage of the electrostatic discharge protection structure are high, the flow of electric charge may pass through the components to be protected and cause damage to the components before the electrostatic discharge protection structure is turned on.

### SUMMARY

The present disclosure provides semiconductor devices including electrostatic discharge protection structures with a low breakdown voltage and a low trigger voltage, and thus the semiconductor devices according to the present disclosure have good efficiency and reliability.

According to an embodiment of the present disclosure, a semiconductor device is provided. The semiconductor device includes a substrate, a source region in the substrate, a drain region in the substrate, a gate structure on the substrate and a first well in the substrate. The drain region has a drain sidewall facing toward the source region. The gate structure is between the drain region and the source region. The gate structure has a first gate sidewall facing toward the drain region. The first well is underneath the drain region. The first well has a well sidewall facing toward the source region. A first distance between the first gate sidewall and the drain sidewall is less than or equal to a second distance between the first gate sidewall and the well sidewall.

According to an embodiment of the present disclosure, a semiconductor device is provided. The semiconductor device includes a substrate, a source region in the substrate, a drain region in the substrate, a gate structure on the substrate, and a first well in the substrate. The gate structure is between the drain region and the source region. The gate structure has a gate sidewall facing toward the drain region. The first well is underneath the drain region. The first well has a well sidewall facing toward the source region. The well sidewall is aligned or substantially aligned with the gate sidewall.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a layout of a semiconductor device according to an embodiment of the present disclosure.

FIG. 2 illustrates a schematic cross-sectional view of a semiconductor device according to an embodiment of the present disclosure.

FIG. 3 illustrates a schematic cross-sectional view of a semiconductor device according to another embodiment of the present disclosure.

FIG. 4 illustrates a schematic cross-sectional view of a semiconductor device according to another embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. The illustration uses the same/similar reference numerals to indicate the same/similar elements.

As used in the specification and the appended claims, the ordinals such as “first”, “second” and the like to describe elements do not imply or represent a specific position in the structure, or the order of arrangement, or the order of manufacturing. The ordinals are only used to clearly distinguish multiple elements with the same name. As used in the specification and the appended claims, spatial relation terms such as “on”, “above”, “over”, “upper,” “top”, “below”, “beneath”, “under”, “underneath”, “lower”, “bottom” and the like may be used to describe the relative spatial relations or positional relations between one element(s) and another element(s) as illustrated in the drawings, and these spatial relations or positional relations, unless specified otherwise, can be direct or indirect. The spatial relation terms are intended to encompass different orientations of structures in addition to the orientation depicted in the drawings. The structure can be inverted or rotated by various angles, and the spatial relation descriptions used herein can be interpreted accordingly. As used in the specification and the appended claims, the singular forms “a,” “an,” and “the” are intended to include the plural forms as well, unless the context clearly indicates otherwise. As used in the specification and the appended claims, the term “and/or” includes any and all combinations of one or more of the associated listed items. As used in the specification and the appended claims, term “adjoin” refers to “be adjacent to and contact”.

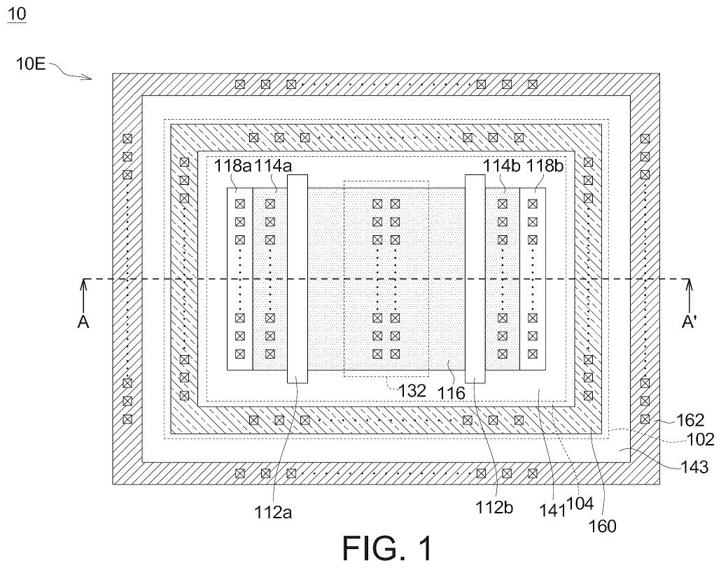

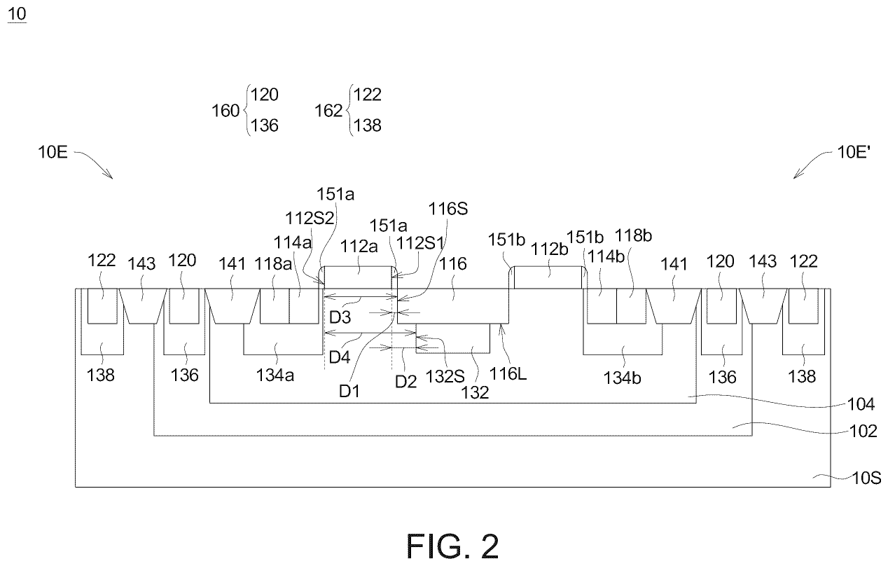

Referring to FIGS. 1 and 2, FIG. 1 illustrates a schematic view of a layout of a semiconductor device 10 according to an embodiment of the present disclosure. A cross-sectional structure of the semiconductor device 10 illustrated along the line AA′ shown in FIG. 1 can be the structure shown in FIG. 2. The semiconductor device 10 includes a substrate 10S and an electrostatic discharge protection structure 10E. The substrate 10S can be formed by a semiconductor material such as monocrystalline silicon, polycrystalline silicon, germanium, diamond, gallium arsenide, silicon carbide, indium arsenide, indium phosphide, silicon germanium carbide, gallium arsenide phosphide, gallium indium phosphide, and any combination thereof. For example, the substrate 10S can be a silicon substrate or a silicon on insulator (SOI) substrate. The substrate 10S may optionally include one or more layers formed on the semiconductor substrate. The substrate 10S includes dopants. For example, the dopants can be an electron donors or electron acceptors. The substrate 10S may have a first conductivity type or a second conductivity type different from the first conductivity type depending on the type of the dopants. For example, the first conductivity type is N-type, and the second conductivity type is P-type. The electrostatic discharge protection structure 10E is in the substrate 10S. The electrostatic discharge protection structure 10E can be an extended-drain metal oxide semiconductor field-effect transistor (MOSFET) or a laterally diffused MOSFET. The following description uses the substrate 10S having the second conductivity type (P-type) and a N-type extended-drain MOSFET as embodiments to illustrate the present disclosure, but the present disclosure is not limited thereto.

The electrostatic discharge protection structure 10E includes a source region 114a, a drain region 116, a gate structure 112a and a first well 132. The source region 114a is in the substrate 10S. The drain region 116 is in the substrate 10S. The gate structure 112a is on the substrate 10S. The gate structure 112a is between the source region 114a and the drain region 116. The first well 132 is in the substrate 10S. At least a portion of the first well 132 is underneath the drain region 116. The drain region 116 has a drain sidewall 116S facing toward the source region 114a. The gate structure 112a has a first gate sidewall 112S1 facing toward the drain region 116. The first well 132 has a well sidewall 132S facing toward the source region 114a. A first distance D1 (in a lateral direction) between the first gate sidewall 112S1 and the drain sidewall 116S is less than a second distance D2 (in the lateral direction) between the first gate sidewall 112S1 and the well sidewall 132S. The second distance D2 can be less than or equal to 2 micrometers. The second distance D2 can be greater than or equal to 0 and less than or equal to 2 micrometers. The gate structure 112a may has a second gate sidewall 112S2 opposite to the first gate sidewall 112S1. The second gate sidewall 112S2 can face toward the source region 114a. A distance D3 (in the lateral direction) between the second gate sidewall 112S2 and the drain sidewall 116S is less than a fourth distance D4 (in the lateral direction) between the second gate sidewall 112S2 and the well sidewall 132S.

In the present embodiment, the first well 132 is completely underneath the drain region 116, and a width of the drain region 116 in the lateral direction is greater than a width of the first well 132 in the lateral direction. A lower surface 116L of the drain region 116 is not completely covered by the first well 132. The drain sidewall 116S of the drain region 116 may not contact the first well 132.

The drain sidewall 116S of the drain region 116 can be between the well sidewall 132S of the first well 132 and the first gate sidewall 112S1 of the gate structure 112a. The gate structure 112a and the first well 132 are disposed in a non-overlap manner in a longitudinal direction. The arrangement of the first well 132 can cause the current to flow downward and away from the surface, thereby improving the electrostatic discharge protection capability.

The electrostatic discharge protection structure 10E can further include a second well 134a, a third well 104, a deep well 102, a doped region 118a, an isolation structure 141, a guard ring 160, an isolation structure 143, a guard ring 162 and a spacer 151a. The second well 134a, the third well 104 and the deep well 102 are in the substrate 10S. The third well 104 is in the deep well 102. As shown in FIG. 1, the deep well 102 surrounds the third well 104. The deep well 102 surrounds the source region 114a and the drain region 116. The drain region 116, the source region 114a, the doped region 118a, the first well 132 and the second well 134a are in the third well 104. A portion of the lower surface 116L of the drain region 116 can contact the third well 104. The drain sidewall 116S of the drain region 116 and the well sidewall 132S of the first well 132 can contact the third well 104. The drain region 116 and the first well 132 are isolated from the substrate 10S by the third well 104. The doped region 118a and the source region 114a are in the second well 134a. The doped region 118a may adjoin the source region 114a. The source region 114a can be between the gate structure 112a and the doped region 118a. The doped region 118a and the source region 114a can be isolated from the third well 104 by the second well 134a. The isolation structure 141 can be between the doped region 118a and the guard ring 160. A portion of the isolation structure 141 is in the second well 134a. A portion of the isolation structure 141 is in the third well 104. A portion of the isolation structure 141 is in the deep well 102. As shown in FIG. 1, the isolation structure 141 may have a ring shape.

The guard ring 160 is in the substrate 10S. The guard ring 160 includes a doped region 120 and a fourth well 136. The fourth well 136 is in the deep well 102. The doped region 120 is in the fourth well 136. As shown in FIG. 1, the guard ring 160 may have a ring shape. The guard ring 160 may surround the gate structure 112a, the drain region 116, the source region 114a, the doped region 118a and the isolation structure 141. The guard ring 162 is in the substrate 10S. The guard ring 162 includes a doped region 122 and a fifth well 138. The fifth well 138 is in the substrate 10S. The doped region 122 is in the fifth well 138. As shown in FIG. 1, the guard ring 162 may have a ring shape. The guard ring 162 may surround the guard ring 160. The isolation structure 143 is between the doped region 120 of the guard ring 160 and the doped region 122 of the guard ring 162. A portion of the isolation structure 143 is in the fourth well 136. A portion of the isolation structure 143 is in the deep well 102. A portion of the isolation structure 143 is in the substrate 10S. A portion of the isolation structure 143 is in the fifth well 138. As shown in FIG. 1, the isolation structure 143 may have a ring shape. The spacer 151a can be formed on the first gate sidewall 112S1 and the second gate sidewall 112S2 of the gate structure 121a. For example, the isolation structure 141 and the isolation structure 143 can be shallow trench isolation (STI) structures.

In the present embodiment, the source region 114a, the drain region 116, the first well 132, the deep well 102, the doped region 120 and the fourth well 136 have the first conductivity type (N-type); the second well 134a, the third well 104, the doped region 118a, the doped region 122 and the fifth well 138 and the second conductivity type (P-type). Dopants may be introduced into the substrate 10S to define the source region 114a, the drain region 116, the first well 132, the second well 134a, the third well 104, the fourth well 136, the fifth well 138, the deep well 102, the doped region 118a, the doped region 120 and the doped region 122. The source region 114a, the drain region 116, the doped region 118a, the doped region 120 and the doped region 122 can be heavy doped regions.

The semiconductor device 10 can further include an electrostatic discharge protection structure 10E′ in the substrate 10S. The electrostatic discharge protection structure 10E′ includes a source region 114b, the drain region 116, a gate structure 112b, the first well 132, a second well 134b, the third well 104, the deep well 102, a doped region 118b, the isolation structure 141, the guard ring 160, the isolation structure 143, the guard ring 162 and a spacer 151b. The configuration of components of the electrostatic discharge protection structure 10E′ can be symmetrical to the configuration of components of the electrostatic discharge protection structure 10E. The electrostatic discharge protection structure 10E′ and the electrostatic discharge protection structure 10E share the drain region 116, the first well 132, the third well 104, the deep well 102, the isolation structure 141, the guard ring 160, the isolation structure 143, and the guard ring 162. The source region 114b of the electrostatic discharge protection structure 10E′ can be similar to the source region 114a of the electrostatic discharge protection structure 10E. The gate structure 112b of the electrostatic discharge protection structure 10E′ can be similar to the gate structure 112a of the electrostatic discharge protection structure 10E. The second well 134b of the electrostatic discharge protection structure 10E′ can be similar to the second well 134a of the electrostatic discharge protection structure 10E. The doped region 118b of the electrostatic discharge protection structure 10E′ can be similar to the doped region 118a of the electrostatic discharge protection structure 10E. The space 151b of the electrostatic discharge protection structure 10E′ can be similar to the space 151a of the electrostatic discharge protection structure 10E. The electrostatic discharge protection structure 10E′ can be used for electrostatic discharge together with the electrostatic discharge protection structure 10E.

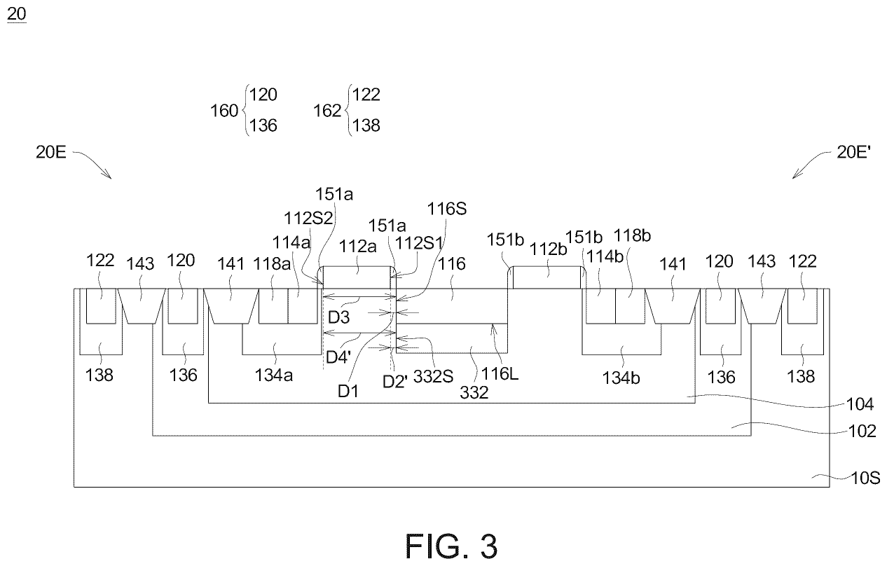

The electrostatic discharge protection structure according to the present disclosure is not limited to the structures shown in FIGS. 1 and 2. In other embodiments, the drain sidewall of the drain region can be aligned or substantially aligned with the well sidewall of the first well, as shown in FIG. 3. In FIG. 3, the semiconductor device 20 includes the substrate 10S and the electrostatic discharge protection structure 20E, and the drain sidewall 116S of the drain region 116 of the electrostatic discharge protection structure 20E is aligned or substantially aligned with the well sidewall 332S of the first well 332 in the longitudinal direction. The first well 332 is completely underneath the drain region 116. A width of the drain region 116 in the lateral direction is equal to or substantially equal to a width of the first well 332 in the lateral direction. A lower surface 116L of the drain region 116 is completely covered by the first well 332. The drain sidewall 116S of the drain region 116 may not contact the first well 332. The drain sidewall 116S of the drain region may contact the third well 104. The gate structure 112a and the first well 332 are disposed in a non-overlap manner in the longitudinal direction. A first distance D1 (in the lateral direction) between the first gate sidewall 112S1 and the drain sidewall 116S is equal to or substantially equal to a second distance D2′ (in the lateral direction) between the first gate sidewall 112S1 and the well sidewall 332S. The second distance D2′ can be less than or equal to 2 micrometers. The second distance D2′ can be greater than or equal to 0 and less than or equal to 2 micrometers. A distance D3 (in the lateral direction) between the second gate sidewall 112S2 and the drain sidewall 116S is equal to or substantially equal to a fourth distance D4′ (in the lateral direction) between the second gate sidewall 112S2 and the well sidewall 332S. The first well 332 has the first conductivity type (N-type). The semiconductor device 20 may further includes an electrostatic discharge protection structure 20E′. The configuration of components of the electrostatic discharge protection structure 20E′ can be symmetrical to the configuration of components of the electrostatic discharge protection structure 20E. The electrostatic discharge protection structure 20E′ and the electrostatic discharge protection structure 20E share the drain region 116, the first well 332, the third well 104, the deep well 102, the isolation structure 141, the guard ring 160, the isolation structure 143, and the guard ring 162.

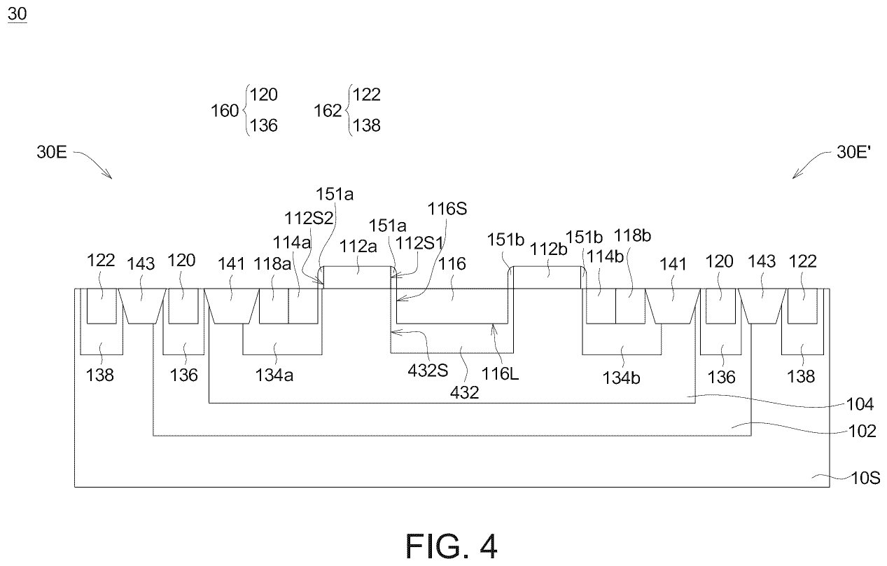

In other embodiments, the well sidewall of the first well can be aligned or substantially aligned with the first gate sidewall of the gate structure, as shown in FIG. 4. In FIG. 4, the semiconductor device 30 includes the substrate 10S and the electrostatic discharge protection structure 30E, and the well sidewall 432S of the first well 432 of the electrostatic discharge protection structure 30E is aligned or substantially aligned with the first gate sidewall 112S1 of the gate structure 112a in the longitudinal direction. A second distance (in the lateral direction) between the well sidewall 432S and the first gate sidewall 112S1 can be equal to or substantially equal to 0. A portion of the first well 432 is underneath the drain region 116, and another portion of the first well 432 is on the drain sidewall 116S of the drain region 116. The drain sidewall 116S of the drain region 116 can be covered by the first well 432. The drain sidewall 116S of the drain region 116 may not contact the third well 104. A width of the drain region 116 in the lateral direction is less than a width of the first well 432 in the lateral direction. A lower surface 116L of the drain region 116 is completely covered by the first well 432. The gate structure 112a and the first well 432 are disposed in a non-overlap manner in the longitudinal direction. The first well 432 has the first conductivity type (N-type). The semiconductor device 30 may further includes an electrostatic discharge protection structure 30E′. The configuration of components of the electrostatic discharge protection structure 30E′ can be symmetrical to the configuration of components of the electrostatic discharge protection structure 30E. The electrostatic discharge protection structure 30E′ and the electrostatic discharge protection structure 30E share the drain region 116, the first well 432, the third well 104, the deep well 102, the isolation structure 141, the guard ring 160, the isolation structure 143, and the guard ring 162.

The electrostatic discharge protection structure according to the present disclosure can decrease breakdown voltage and trigger voltage by adjusting the size of the first well. For example, the breakdown voltage and trigger voltage can be decreased by adjusting the second distance between the well sidewall of the first well and the first gate sidewall of the gate structure. The present disclosure will be explained in further detail with reference to following examples and comparative examples. However, the present disclosure is not limited to these examples.

Examples 1 to 4 is the semiconductor devices shown in FIGS. 2 to 4. In Example 1, the second distance (in the lateral direction) between the first gate sidewall of the gate structure and the well sidewall of the first well of the semiconductor device is equal to 0 micrometer (μm), that is, the first gate sidewall is aligned or substantially aligned with the well sidewall. In Example 2, the second distance (in the lateral direction) between the first gate sidewall of the gate structure and the well sidewall of the first well of the semiconductor device is equal to 0.5 micrometers, and the gate structure and the first well are disposed in a non-overlap manner in the longitudinal direction, that is, the first well is completely on one side of the gate structure. In Example 3, the second distance (in the lateral direction) between the first gate sidewall of the gate structure and the well sidewall of the first well of the semiconductor device is equal to 1 micrometers, and the gate structure and the first well are disposed in a non-overlap manner in the longitudinal direction, that is, the first well is completely on one side of the gate structure. In Example 4, the second distance (in the lateral direction) between the first gate sidewall of the gate structure and the well sidewall of the first well of the semiconductor device is equal to 2 micrometers, and the gate structure and the first well are disposed in a non-overlap manner in the longitudinal direction, that is, the first well is completely on one side of the gate structure. In Comparative Example 1, the first well covers the drain sidewall of the drain region of the semiconductor device, and the first well extends to a position below the gate structure; that is, a portion of the first well overlaps the gate structure in the longitudinal direction; a distance (in the lateral direction) between the first gate sidewall of the gate structure and the well sidewall of the first well is equal to 0.3 micrometers. DC bias voltage is applied to the semiconductor devices of Examples 1 to 4 and Comparative Example 1 to obtain their breakdown voltage (VBD), TLP (Transmission Line Pulse) tests are performed to the semiconductor devices of Examples 1 to 4 and Comparative Example 1 to obtain their trigger voltage (Vₜ₁) and second breakdown current (Iₜ₂), and the results are shown in the following TABLE 1. In addition, human body model (HBM) and machine model (MM) are used for testing the electrostatic discharge protection capability of the semiconductor devices of Examples 1 to 4 and Comparative Example 1, and the results are shown in the following TABLE 1.

TABLE 1

| | | |
|---|---|---|
| DC | TLP | ESD |

| | V_{BD} | Vₜ₁ | Iₜ₂ | HBM | MM |
|---|---|---|---|---|---|
| | (V) | (V) | (A) | (kV) | (V) |
| Example 1 | 25.3 | 26.3 | 4.54 | 7.2 | 200 |
| Example 2 | 24.4 | 25.2 | 4.32 | 7 | 225 |
| Example 3 | 22 | 25.1 | 4.35 | 4.6 | 250 |
| Example 4 | 21.4 | 24.2 | 4.53 | 4.6 | 225 |
| Comparative | 27.4 | 28.3 | 4.22 | 5.4 | 325 |
| Example 1 | | | | | |

As shown in TABLE 1, the breakdown voltages of the semiconductor devices of Examples 1 to 4 are all smaller than the breakdown voltage of Comparative Example 1, and the breakdown voltage decreases as the second distance increases. The trigger voltages of the semiconductor devices of Examples 1 to 4 are all smaller than the trigger voltage of Comparative Example 1, and the trigger voltage decreases as the second distance increases. The semiconductor devices of Examples 1 to 4 still have high second breakdown current, which means that they have good electrostatic discharge protection capabilities. The values of the semiconductor devices of Examples 1 to 4 obtained by human body model are all greater than 2 kV, and the values of the semiconductor devices of Examples 1 to 4 obtained by machine model are not significantly decreased, which means that the semiconductor device according to the present disclosure has good electrostatic discharge protection capabilities.

The configuration of the semiconductor device according to the present disclosure can effectively decrease the breakdown voltage and the trigger voltage, and can maintain good electrostatic discharge protection capability. As such, the efficiency and reliability of electrostatic discharge protection structure can be improved.

It is noted that the structures as described above are provided for illustration. The disclosure is not limited to the configurations disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor device, comprising:
a substrate;
a source region in the substrate;
a drain region in the substrate and having a drain sidewall facing toward the source region;
a gate structure on the substrate and between the drain region and the source region, wherein the gate structure has a first gate sidewall facing toward the drain region; and
a first well in the substrate and underneath the drain region, wherein the first well has a well sidewall facing toward the source region,
wherein a first distance between the first gate sidewall and the drain sidewall is less than or equal to a second distance between the first gate sidewall and the well sidewall.

2. The semiconductor device according to claim 1, wherein the drain sidewall of the drain region is between the well sidewall of the first well and the first gate sidewall of the gate structure.

3. The semiconductor device according to claim 1, wherein the gate structure has a second gate sidewall opposite to the first gate sidewall, a third distance between the second gate sidewall and the drain sidewall is less than or equal to a fourth distance between the second gate sidewall and the well sidewall.

4. The semiconductor device according to claim 1, wherein the first well is completely underneath the drain region.

5. The semiconductor device according to claim 4, wherein a width of the drain region is greater than or equal to a width of the first well.

6. The semiconductor device according to claim 1, wherein the drain sidewall is aligned or substantially aligned with the well sidewall of the first well.

7. The semiconductor device according to claim 1, wherein the source region has a first conductivity type, the drain region has the first conductivity type, and the first well has the first conductivity type.

8. The semiconductor device according to claim 7, wherein the first conductivity type is N-type.

9. The semiconductor device according to claim 1, further comprising:
a second well in the substrate, wherein the source region is in the second well; and
a third well in the substrate, wherein the drain region, the source region, the first well and the second well are in the third well,
wherein the drain sidewall of the drain region contacts the third well.

10. The semiconductor device according to claim 9, wherein the source region has a first conductivity type, the drain region has the first conductivity type, the first well has the first conductivity type, the second well has a second conductivity type, the third well has the second conductivity type, and the first conductivity type is different from the second conductivity type.

11. The semiconductor device according to claim 10, further comprising a deep well in the substrate and having the first conductivity type, the third well is in the deep well.

12. The semiconductor device according to claim 9, wherein a portion of a lower surface of the drain region contacts the third well.

13. The semiconductor device according to claim 1, wherein the gate structure and the first well are disposed in a non-overlap manner.

14. The semiconductor device according to claim 1, wherein the second distance is less than or equal to 2 micrometers.

15. A semiconductor device, comprising:
a substrate;
a source region in the substrate;
a drain region in the substrate;
a gate structure on the substrate and between the drain region and the source region, wherein the gate structure has a gate sidewall facing toward the drain region; and
a first well in the substrate and underneath the drain region, wherein the first well has a well sidewall facing toward the source region,
wherein the well sidewall is aligned or substantially aligned with the gate sidewall.

16. The semiconductor device according to claim 15, further comprising:
a second well in the substrate, wherein the source region is in the second well; and
a third well in the substrate, wherein the drain region, the source region, the first well and the second well are in the third well.

17. The semiconductor device according to claim 16, wherein the source region has a first conductivity type, the drain region has the first conductivity type, the first well has the first conductivity type, the second well has a second conductivity type, the third well has the second conductivity type, and the first conductivity type is different from the second conductivity type.

18. The semiconductor device according to claim 17, wherein the substrate has the second conductivity type, and the drain region and the first well are isolated from the substrate by the third well.

19. The semiconductor device according to claim 17, further comprising a deep well in the substrate and having the first conductivity type, the deep well surrounds the source region and the drain region.

20. The semiconductor device according to claim 15, further comprising a first guard ring and a second guard ring, the first guard ring is in the substrate and surrounds the source region, the drain region and the gate structure, the second guard ring is in the substrate and surrounds the first guard ring, the first guard ring has a first conductivity type, the second guard ring has a second conductivity type different from the first conductivity type.
